(19) United States
(12) Patent Application Publication
(10) Pub. No.: US 2026/0247561 A1
(43) Pub. Date: Aug. 20, 2026

(54) Server System Component Bay System

(71) Applicant: Dell Products L.P., Round Rock, TX (US)

(72) Inventors: Yufeng Lin, Da'an District (TW); Yi-Chang Chen, New Taipei City (TW); Haocheng Ku, Taipei City (TW); Kuang-Hsi Lin, Bade District (TW); Pei-Chuan Hsieh, Xizhi District (TW); Po Li Hsieh, Taoyuan (TW)

(21) Appl. No.: 19/058,511

(22) Filed: Feb. 20, 2025

(51) Int. Cl. H05K 7/14

(52) U.S. Cl. CPC H05K 7/1489

(57) ABSTRACT

A bay system for use with a storage system for an information handling system. The bay includes a host processor module portion, the host processor module portion comprising a plurality of module receiving connectors and a chassis component portion, the chassis component portion comprising a plurality of module bays, each of the plurality of module receiving connectors being associated with a respective module bay of the plurality of module bays, each of the plurality of module bays including respective module installation features, the respective module installation features ensuring a particular type of module may only be installed in a particular module bay of the plurality of module bays.

### BACKGROUND OF THE INVENTION

### Field of the Invention

The present invention relates to information handling systems. More specifically, embodiments of the invention relate to server type information handling systems within information technology (IT) environments.

### Description of the Related Art

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

It is known to use information handling systems and related IT systems within information technology (IT) environments such as data centers.

### SUMMARY OF THE INVENTION

A system and method for providing a server system with a bay system.

In one embodiment, the invention relates to chassis component for use with bay system of an information handling system, comprising: a chassis component portion, the chassis component portion comprising a plurality of module bays, each of a plurality of module receiving connectors being associated with a respective module bay of the plurality of module bays, each of the plurality of module bays including respective module installation features, the respective module installation features ensuring a particular type of module may only be installed in a particular module bay of the plurality of module bays.

In another embodiment, the invention relates to a bay system of an information handling system comprising: a host processor module portion, the host processor module portion comprising a plurality of module receiving connectors; and, a chassis component portion, the chassis component portion comprising a plurality of module bays, each of the plurality of module receiving connectors being associated with a respective module bay of the plurality of module bays, each of the plurality of module bays including respective module installation features, the respective module installation features ensuring a particular type of module may only be installed in a particular module bay of the plurality of module bays.

In another embodiment, the invention relates to a system comprising: a host processor module, the host processor module including a host processor module portion and a processor, the host processor module portion comprising a plurality of module receiving connectors; and, a chassis, the chassis including a chassis component portion, the host processor module portion and the chassis component portion providing a bay system, the chassis component portion comprising a plurality of module bays, each of the plurality of module receiving connectors being associated with a respective module bay of the plurality of module bays, each of the plurality of module bays including respective module installation features, the respective module installation features ensuring a particular type of module may only be installed in a particular module bay of the plurality of module bays.

### BRIEF DESCRIPTION OF THE DRAWINGS

The present invention may be better understood, and its numerous objects, features and advantages made apparent to those skilled in the art by referencing the accompanying drawings. The use of the same reference number throughout the several figures designates a like or similar element.

FIG. 1 shows a general illustration of components of an information handling system as implemented in the system and method of the present invention.

FIG. 2 shows a perspective view of a portion of a data center within an IT environment.

FIG. 3 shows a generalized perspective view of an example server type information handling system.

FIGS. 4A and 4B, generally referred to as FIG. 4, show top views of information handling system modules.

FIGS. 5A, 5B and 5C, generally referred to as FIG. 5, show views of a bay system.

FIGS. 6A and 6B, generally referred to as FIG. 6, show views of information handling systems.

### DETAILED DESCRIPTION

Various aspects of the disclosure include an appreciation that it is known to provide information handling systems with modules such local area network (LAN) modules and storage modules. Various aspects of the present disclosure include an appreciation that the modules can include boot optimized storage system (BOSS) type modules, open compute project (OCP) type modules and data center secure control module (DC-SCM) type modules. Various aspects of the present disclosure include an appreciation that the modules often conform to particular device specifications. Various aspects of the present disclosure include an appreciation that one such device specification is the BOSS device specification. Various aspects of the present disclosure include an appreciation that another such device specification is the OCP device specification. Various aspects of the present disclosure include an appreciation that another such device specification is the data center secure control module (DC-SCM) device specification. Various aspects of the present disclosure include an appreciation that device specifications often define particular dimensions for the modules to conform to the device specification.

Various aspects of the present disclosure include an appreciation that the modules may be configured as LAN on motherboard (LOM) type modules, rear input/output (RIO) type modules, or a combination thereof. Various aspects of the present disclosure include an appreciation that information handling systems may be configured with combinations of modules, such as boot optimized storage system type storage component type modules, OCP type modules, DC-SCM type modules, or a combination thereof, each of which may be mounted in a respective bay of the information handing system. Various aspects of the present disclosure include an appreciation that each respective bay may have particular mounting configurations. Various aspects of the present disclosure include an appreciation that the particular mounting configurations may be defined by the device specification. Various aspects of the present disclosure include an appreciation that the particular mounting configurations can include mounting dimensions, receiving connector locations, module mounting mechanisms (e.g., rails and latches), or a combination thereof.

Various aspects of the present disclosure include an appreciation that it is known to configure information handling systems with a host processor module (HPMs (also referred to as a planar or motherboard). Various aspects of the present disclosure include an appreciation that the host processor module is often mounted to a chassis component (often referred to as a tempan). Various aspects of the present disclosure include an appreciation that a host processor module may be configured according to a plurality of different dimensions. Various aspects of the present disclosure include an appreciation that the host processor module configured according to a particular dimension, is mounted to a chassis component associated with the particular dimension. Various aspects of the present disclosure include an appreciation that the different dimensions may include a short chassis component type dimension and a long chassis component type dimension. Various aspects of the present disclosure include an appreciation that the short chassis component type dimension and the long chassis component type dimension refer to an amount of depth the host processor module occupies within a chassis in which the host processor module is mounted. Various aspects of the present disclosure include an appreciation that a host processor module and chassis component corresponding to the short chassis component type dimension extend across a portion (e.g., substantially (i.e., +/−20%) 60 %) of the depth of the chassis whereas a host processor module and chassis component corresponding to the long chassis component type dimension extend across most (e.g., substantially (i.e., +/−20%) 90 %) of the depth of the chassis.

Various aspects of the present disclosure include an appreciation that the mounting of an HPM of a particular dimension may be affected by a rack unit size of the information handling system. For example, a short chassis component type HPM may be mounted within an information handling system conforming to a 1U server size whereas a long chassis component type HPM may be mounted within an information handling system conforming to a 2U server size. Various aspects of the present disclosure include an appreciation that known long chassis component type HPMs often have less flexibility to be mounted within chassis having different server size form factors.

Various aspects of the present disclosure include an appreciation that known HPMs often includes one or more bays for receiving modules which are also secured to the chassis component associated with the HPM. Various aspects of the present disclosure include an appreciation that servicing rear mounted modules can be challenging as the servicing can often require removing the HPM from the chassis, as the modules are often secured to the chassis component. Various aspects of the present disclosure include an appreciation that servicing rear mounted modules can be especially challenging with long chassis component type HPMs as the servicing can often require removing the HPM from the chassis, as the modules are often secured to the chassis component.

A system and method are disclosed for providing a server type information handling system with a bay system. In certain embodiments, the bay system includes a host processor module portion, a chassis component portion, or a combination thereof. In certain embodiments, the bay system is associated with a short chassis component type HPM. In certain embodiments, the bay system is configured to accommodate a plurality of different modules. In certain embodiments, the modules include a DC-SCM module, a BOSS module, an OCP module, or a combination thereof.

In certain embodiments, the bay system is configured to enable information handling system rear side installation of the modules. In certain embodiments, the bay system prevents BOSS storage components, OCP type components, DC-SCM components, or a combination thereof, from being mounted in an incorrect bay. In certain embodiments, particular bays of the bay system include respective module installation features. In certain embodiments, the module installation features guarantee that a particular module can only be installed into a correct bay of the bay system. In certain embodiments, module installation features are associated with the chassis component.

In certain embodiments, the module mounting mechanisms (e.g., rails and latches) that secure respective modules are physically located on a chassis component of the information handling system. In certain embodiments, the module mounting mechanisms (e.g., rails and latches) that secure respective modules are physically located on a base portion of the chassis of the information handling system. In certain embodiments, the base portion of the chassis includes the chassis component.

In certain embodiments, the chassis component is designed to fit the outline of the HPM. In certain embodiments, the outline of the HPM includes a detachable fan board. In certain embodiments, the chassis component is configured to enable tool-less attachment of the HPM. In certain embodiments, the chassis component includes rear retention features. In certain embodiments, the rear retention features secure the HPM to the chassis component. In certain embodiments, the rear retention features secure the HPM to the chassis component along a plurality of axis. In certain embodiments, the rear retention features secure the HPM to the chassis component along three axes.

Such a bay system advantageously accommodates a plurality of different modules via a single bay system design. In certain embodiments, the plurality of modules includes a DC-SCM module, a BOSS module, an OCP module, or a combination thereof. In certain embodiments, the BOSS module comprises a BOSS N-1 type module. In certain embodiments, the OCP module comprises an OCP form factor M.2 interposer type module. Such a bay system advantageously provides a short chassis component type HPM which can accommodate a plurality of different modules. Such a bay system advantageously provides a short chassis component type HPM which can accommodate externally, rear chassis accessible different modules.

In certain embodiments, the storage system comprises a boot optimized storage system. In certain embodiments, the boot optimized storage system comprises a redundant array of independent disks (RAID) solution optimized for booting an operating system of a server. In certain embodiments, the boot optimized storage system comprises a plurality of serial advanced technology advancement (SATA) solid state devices (SSDs), a host interface (such as a PCIe host interface), a device interface (such as a SATA device interface), or a combination thereof. In certain embodiments, the solid state devices are included within a storage card. In certain embodiments, the storage card corresponds to an M.2 type storage card. In certain embodiments, the storage card corresponds to a boot optimized storage system M.2 type storage card.

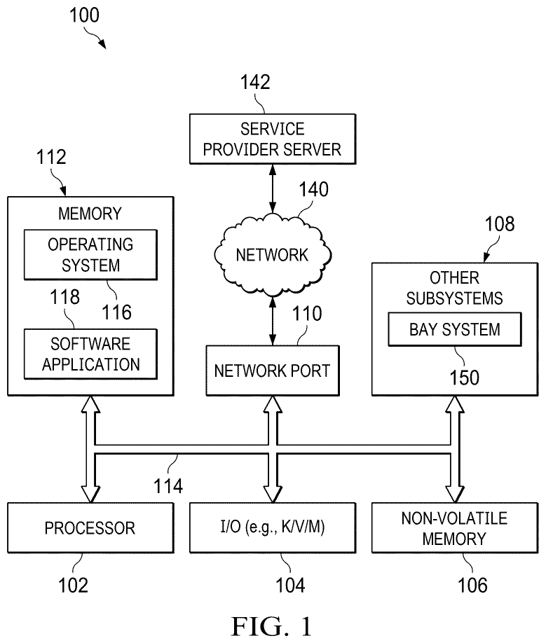

FIG. 1 shows a generalized illustration of an information handling system 100 that can be used to implement the system and method of the present invention. The information handling system 100 includes a processor (e.g., central processor unit or “CPU”) 102, input/output (I/O) devices 104, such as a display, a keyboard, a mouse, and associated controllers, a hard drive or disk storage 106, and various other subsystems 108. In various embodiments, the information handling system 100 also includes network port 110 operable to connect to a network 140, which is likewise accessible by a service provider server 142. In various embodiments, the other subsystems 108 include a bay system 150. The information handling system 100 likewise includes system memory 112, which is interconnected to the foregoing via one or more buses 114. System memory 112 further comprises operating system (OS) 116. In certain embodiments, the information handling system 100 is one of a plurality of information handling systems within a data center. In certain embodiments, the information handling system 100 comprises a server type information handling system. In certain embodiments, the server type information handling system is configured to be mounted within a server rack. In certain embodiments, the other subsystem 108 includes one or more power supplies for supplying power to the other components of the information handling system 100.

In certain embodiments, the information handling system 100 comprises a server type information handling system. In certain embodiments, the server type information handling system comprises a blade server type information handling system. As used herein, a blade server type information handling system broadly refers to an information handling system which is physically configured to be mounted within a server rack.

In certain embodiments, the bay system 150 includes a host processor module portion, a chassis component portion, or a combination thereof. In certain embodiments, the bay system is associated with a short chassis component type HPM. In certain embodiments, the bay system is configured to accommodate a plurality of different modules. In certain embodiments, the modules include a DC-SCM module, a BOSS module, an OCP module, or a combination thereof.

In certain embodiments, the bay system is configured to enable information handling system rear side installation of the modules. In certain embodiments, the bay system prevents BOSS storage components, OCP type storage components, DC-SCM storage components, or a combination thereof, from being mounted in an incorrect bay. In certain embodiments, particular bays of the bay system include respective module installation features. In certain embodiments, the module installation features guarantee that a particular module can only be installed into a correct bay of the bay system. In certain embodiments, module installation features are associated with the chassis component.

In certain embodiments, the module mounting mechanisms (e.g., rails and latches) that secure respective modules are physically located on a chassis component of the information handling system. In certain embodiments, the module mounting mechanisms (e.g., rails and latches) that secure respective modules are physically located on a base portion of the chassis of the information handling system. In certain embodiments, the base portion of the chassis includes the chassis component.

In certain embodiments, the chassis component is designed to fit the outline of the HPM. In certain embodiments, the outline of the HPM includes a detachable fan board. In certain embodiments, the chassis component is configured to enable tool-less attachment of the HPM. In certain embodiments, the chassis component includes rear retention features. In certain embodiments, the rear retention features secure the HPM to the chassis component. In certain embodiments, the rear retention features secure the HPM to the chassis component along a plurality of axis. In certain embodiments, the rear retention features secure the HPM to the chassis component along three axes.

Such a bay system advantageously accommodates a plurality of different modules via a single bay system design. In certain embodiments, the plurality of modules includes a DC-SCM module, a BOSS module, an OCP module, or a combination thereof. In certain embodiments, the BOSS module comprises a BOSS N-1 type module. In certain embodiments, the OCP module comprises an OCP form factor M.2 interposer type module. Such a bay system advantageously provides a short chassis component type HPM which can accommodate a plurality of different modules. Such a bay system advantageously provides a short chassis component type HPM which can accommodate externally, rear chassis accessible different modules.

In certain embodiments, the storage system comprises a boot optimized storage system. In certain embodiments, the boot optimized storage system comprises a redundant array of independent disks (RAID) solution optimized for booting an operating system of a server. In certain embodiments, the boot optimized storage system comprises a plurality of serial advanced technology advancement (SATA) solid state devices (SSDs), a host interface (such as a PCIe host interface), a device interface (such as a SATA device interface), or a combination thereof. In certain embodiments, the solid state devices are included within a storage card. In certain embodiments, the storage card corresponds to an M.2 type storage card. In certain embodiments, the storage card corresponds to a boot optimized storage system M.2 type storage card.

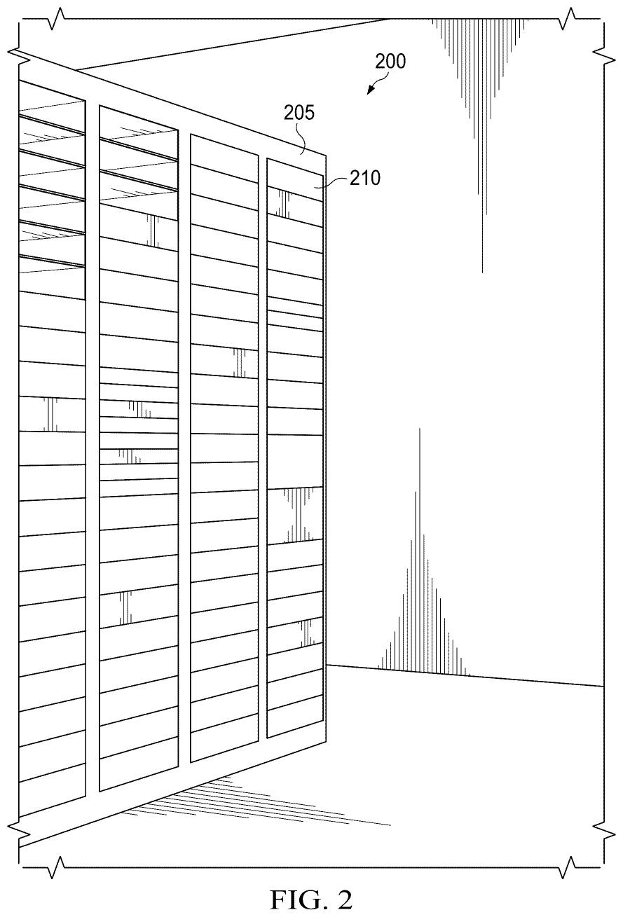

FIG. 2 shows a perspective view of a portion of an IT environment 200. The IT environment includes one or more racks 205 which include a plurality of information handling systems 100, often referred to as a server rack. In various embodiments, the IT environment 200 comprises a data center. As used herein, a data center refers to an IT environment which includes a plurality of networked information handling systems 100. In various embodiments, the information handling systems 100 of the data center include some or all of router type information handling systems, switch type information handling systems, firewall type information handling systems, storage system type information handling systems, server type information handling systems and application delivery controller type information handling systems. In certain environments, the information handling systems 100 are mounted within respective racks. As used herein, a rack refers to a physical structure that is designed to house the information handling systems 100, as well as the associated cabling and power provision for the information handling systems. In certain embodiments, a rack includes side panels to which the information handling systems are mounted. In certain embodiments, the rack includes a top panel and a bottom panel to which the side panels are attached. In certain embodiments, the side panels each include a front side panel and a rear side panel.

In certain embodiments, a plurality of racks is arranged continuous with each other to provide a rack system. An IT environment can include a plurality of rack systems arranged in rows with aisles via which IT service personnel can access information handling systems mounted in the racks. In certain embodiments, the aisles can include front aisles via which the front of the information handling systems may be accessed and hot aisles via which the infrastructure (e.g., data and power cabling) of the IT environment can be accessed.

Each respective rack includes a plurality of vertically arranged information handling systems 210. In certain embodiments, the information handling systems may conform to one of a plurality of standard server sizes. In certain embodiments, the plurality of server sizes conforms to particular rack unit sizes (i.e., rack units). As used herein, a rack unit broadly refers to a standardized server system height. As is known in the art, a server system height often conforms to one of a 1U rack unit, a 2U rack unit, and a 4U rack unit. In general, a 1U rack unit is substantially (i.e., +/−20%) 1.75″ high, a 2U rack unit is substantially (i.e., +/−20%) 3.5″ high, and a 4U rack height is substantially (i.e., +/−20%) 7.0″ high.

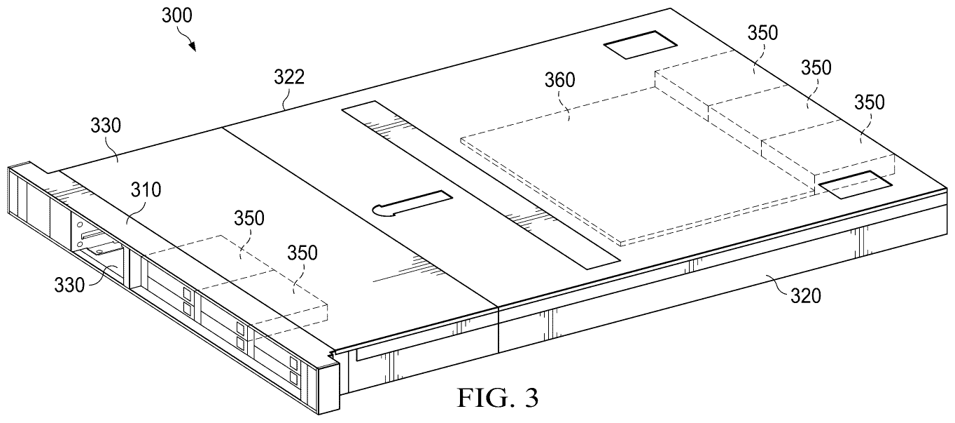

FIG. 3 shows a generalized perspective view of an example blade server type information handling system 300. In certain embodiments, the server type information handling system includes a front portion 310, which is accessible when the server type information handing system 300 is mounted on a server rack. In certain embodiments, the side portions 320, 322 mount to the rack via respective server mounting components. In certain embodiments, the side portions mount to the rack via respective mechanical guiding features which are mechanically coupled to respective server mounting components. In certain embodiments, the server type information handling system can slide out from the rack via the respective mechanical guiding features. In certain embodiments, internal components of the blade type information handling system 300 may be accessed by removing a top panel 330 of the blade type information handing system 300.

In certain embodiments, the blade type information handing system 300 includes a plurality of bays 350 via which components may be mounted to the blade type information handling system. In certain embodiments, the bays 350 are defined by a bay system 360. In certain embodiments, the bay system 360 corresponds to bay system 150.

In certain embodiments, the bay system 360 includes a host processor module portion, a chassis component portion, or a combination thereof. In certain embodiments, the bay system 360 is associated with a short chassis component type HPM. In certain embodiments, the bay system 360 is configured to accommodate a plurality of different modules. In certain embodiments, the modules include a DC-SCM module, a BOSS module, an OCP module, or a combination thereof.

In certain embodiments, the bay system 360 is configured to enable information handling system rear side installation of the modules. In certain embodiments, the bay system 360 prevents BOSS storage components, OCP type storage components, DC-SCM storage components, or a combination thereof, from being mounted in an incorrect bay. In certain embodiments, particular bays of the bay system include respective module installation features. In certain embodiments, the module installation features guarantee that a particular module can only be installed into a correct bay of the bay system. In certain embodiments, module installation features are associated with the chassis component portion.

In certain embodiments, the module mounting mechanisms (e.g., rails and latches) that secure respective modules are physically located on a chassis component of the information handling system. In certain embodiments, the module mounting mechanisms (e.g., rails and latches) that secure respective modules are physically located on a base portion of the chassis of the information handling system. In certain embodiments, the base portion of the chassis includes the chassis component portion.

In certain embodiments, the chassis component is designed to fit the outline of the HPM. In certain embodiments, the outline of the HPM includes a detachable fan board. In certain embodiments, the chassis component is configured to enable tool-less attachment of the HPM. In certain embodiments, the chassis component includes rear retention features. In certain embodiments, the rear retention features secure the HPM to the chassis component. In certain embodiments, the rear retention features secure the HPM to the chassis component along a plurality of axis. In certain embodiments, the rear retention features secure the HPM to the chassis component along three axes.

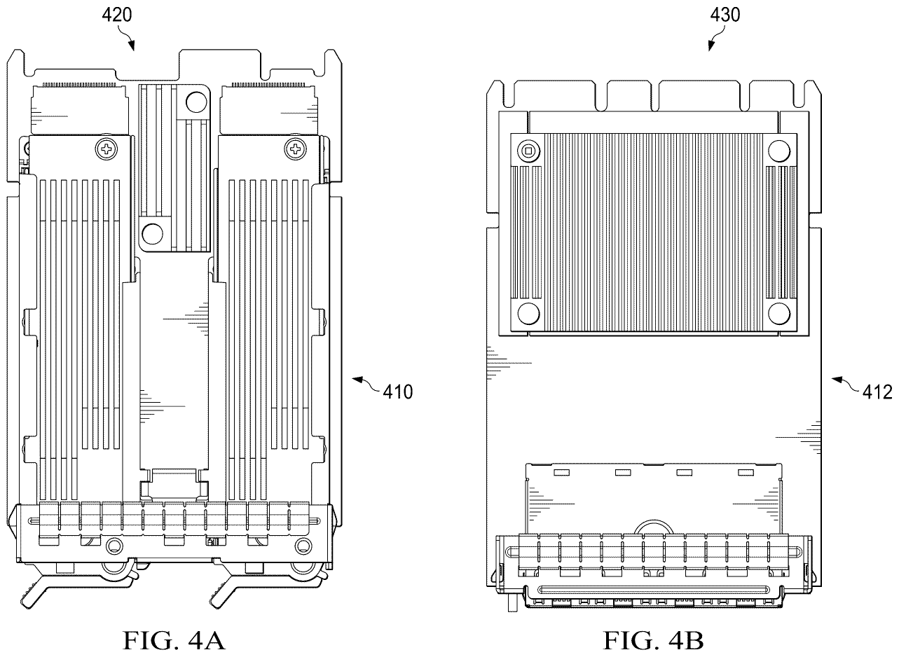

FIGS. 4A and 4B, generally referred to as FIG. 4, show top views of information handling system modules. More specifically FIG. 4A shows a top view of a BOSS type module 410. FIG. 4B shows a top view of an OCP type module 412.

In certain embodiments, the BOSS type module 410 is configured to correspond to the BOSS device specification. In certain embodiments, the dimensions of the BOSS type module 410 conform to dimensions defined by the BOSS device specification. In certain embodiments, the dimensions of the BOSS type module include BOSS width and depth dimensions. In certain embodiments, the BOSS type module 410 includes a corresponding BOSS type rear connector configuration 420. In certain embodiments, the BOSS type rear connector configuration 420 includes a 1C connector. In certain embodiments, the configuration of the corresponding BOSS type rear connector configuration 420 is defined by the BOSS device specification.

In certain embodiments, the OCP type module 412 is configured to correspond to the OCP device specification. In certain embodiments, the dimensions of the OCP type module 412 conform to dimensions defined by the OCP device specification. In certain embodiments, the dimensions of the OCP type module 412 include OCP width and depth dimensions. In certain embodiments, the OCP type module 410 includes a corresponding OCP type rear connector configuration 430. In certain embodiments, the OCP type rear connector configuration 430 includes a 4C connector. In certain embodiments, the configuration of the corresponding OCP type rear connector configuration 430 is defined by the OCP device specification.

In certain embodiments, at least some of the dimensions of the BOSS type module 410 and the OCP type module 412 are substantially similar. In certain embodiments, the substantially similar dimensions could allow a BOSS type module 412 to be mistakenly inserted into an OCP type bay. In certain embodiments, the substantially similar dimensions could allow an OCP type module 412 to be mistakenly inserted into a BOSS type bay.

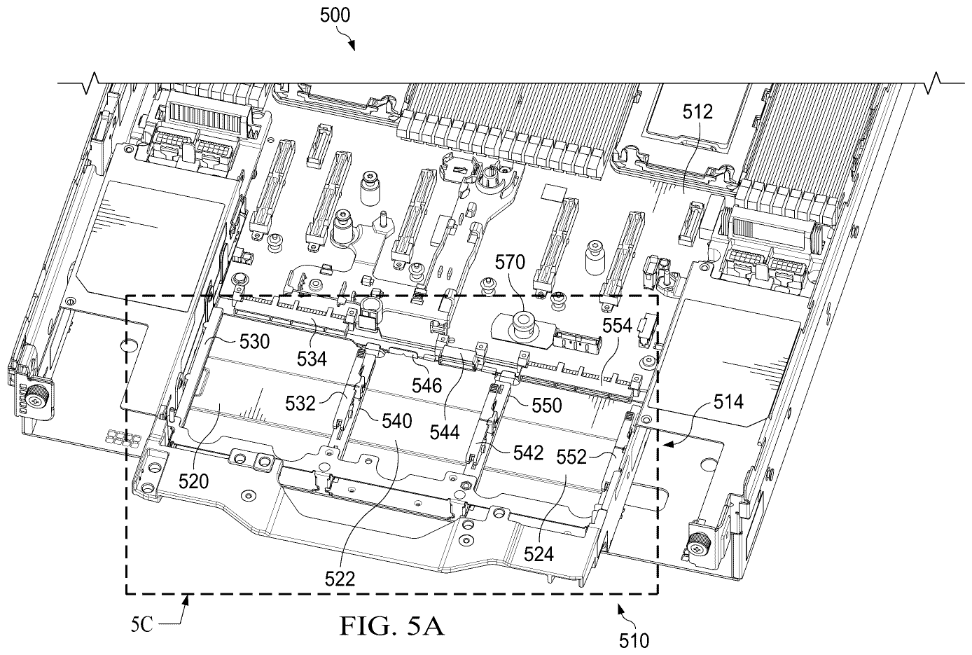

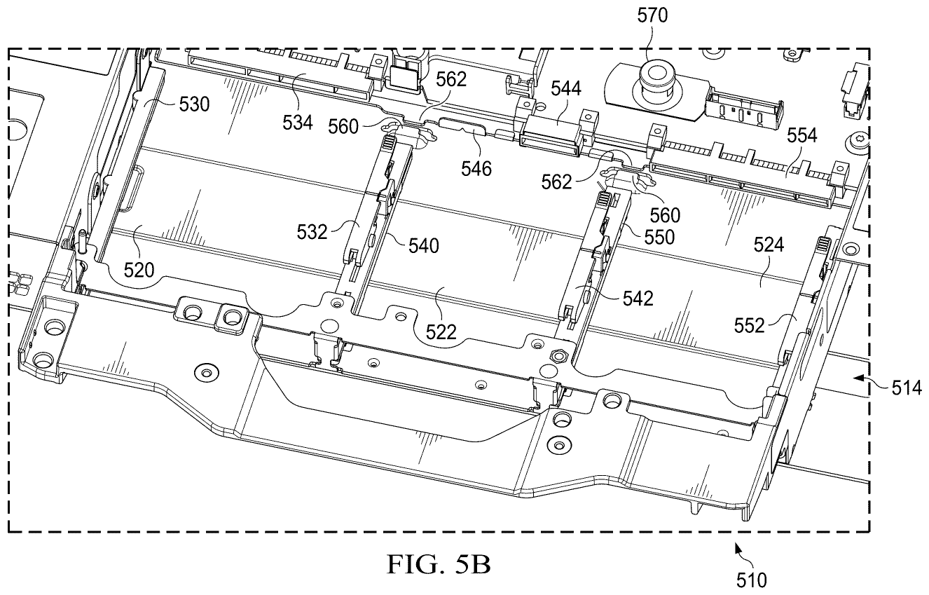

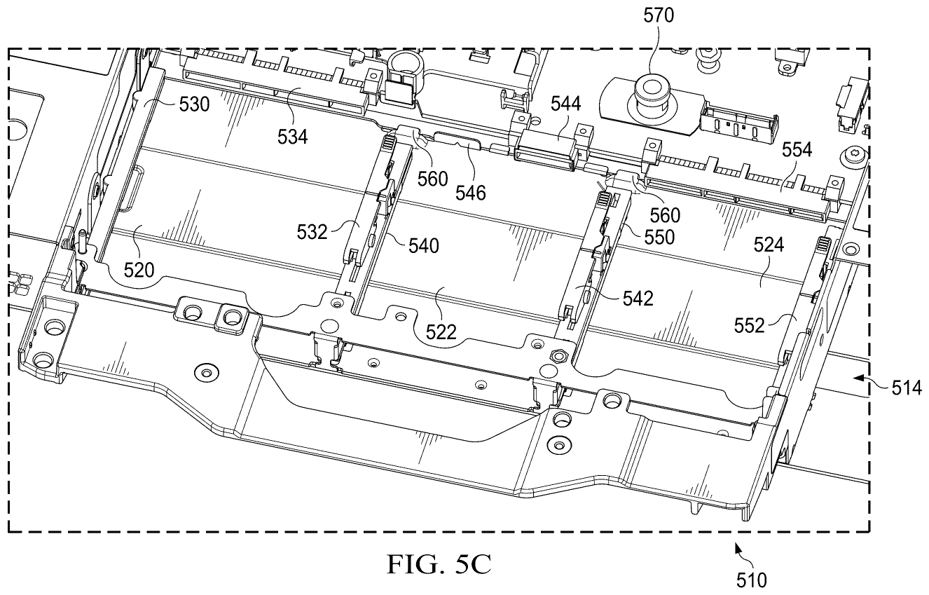

FIGS. 5A, 5B and 5C, generally referred to as FIG. 5, shows views of an information handling system 500 which includes a bay system 510. More specifically, FIG. 5A shows a cut away perspective view of a portion of an information handling system 500 having a bay system 510. FIG. 5B shows a detailed perspective view of a bay system 510 in a first configuration. FIG. 5C shows a detailed perspective view of a bay system 510 in a second configuration. In certain embodiments, the bay system 510 corresponds to bay system 150.

In certain embodiments, the bay system 510 includes a host processor module portion 512, a chassis component portion 514, or a combination thereof. In certain embodiments, the bay system 510 is associated with a short chassis component type HPM. In certain embodiments, the bay system is configured to accommodate a plurality of different modules. In certain embodiments, the modules include a DC-SCM module, a BOSS module, an OCP module, or a combination thereof. In certain embodiments, the bay system 510 includes a DC-SCM module bay 520, a BOSS module bay 522, an OCP module bay 524, or a combination thereof. In certain embodiments, the DC-SCM module bay 520 is configured to receive a DC-SCM module component. In certain embodiments, the BOSS module bay 522 is configured to receive a BOSS module component. In certain embodiments, the OCP module bay 524 is configured to receive an OCP module component.

In certain embodiments, the bay system 510 is configured to enable information handling system rear side installation of the modules. In certain embodiments, the bay system 510 prevents BOSS storage components, OCP type storage components, DC-SCM storage components, or a combination thereof, from being mounted in an incorrect bay. In certain embodiments, particular bays of the bay system include respective module installation features. In certain embodiments, the module installation features guarantee that a particular module can only be installed into a correct bay of the bay system. In certain embodiments, some or all of the module installation features are associated with the chassis component portion 514.

In certain embodiments, the module installation features include bay dimensions, module mounting mechanisms, or a combination thereof. In certain embodiments, the module mounting mechanisms include module rails, module latches, module receiving connectors, or a combination thereof. In certain embodiments, the DC-SCM module bay 520 defines DC-SCM bay dimensions, includes DC-SCM module mounting mechanisms, or a combination thereof. In certain embodiments, the BOSS module bay 522 defines BOSS bay dimensions, includes BOSS module mounting mechanisms, or a combination thereof. In certain embodiments, the OCP module bay 524 defines OCP bay dimensions, includes OCP module mounting mechanisms, or a combination thereof.

In certain embodiments, the DC-SCM module mounting mechanisms include a DC-SCM module rail 530, a DC-SCM module latch 532, a DC-SCM module receiving connector 534, or a combination thereof. In certain embodiments, the DC-SCM module receiving connector 534 includes a 4C DC-SCM module receiving connector. In certain embodiments, the BOSS module mounting mechanisms include a BOSS module rail 540, a BOSS module latch 542, a BOSS module receiving connector 544, or a combination thereof. In certain embodiments, the BOSS module mounting mechanisms further include an insertion prevention mechanism 546. In certain embodiments, the BOSS module receiving connector 544 includes a 1C BOSS module receiving connector. In certain embodiments, the insertion prevention mechanism 546 includes a vertical wall projection. In certain embodiments, the vertical wall projection extends from the chassis component portion 514. In certain embodiments, the insertion prevention mechanism 546 interacts with a portion of a rear connector of a module other than a BOSS type module (e.g., an OCP type rear connector (see e.g., FIG. 4B) or a DC-SCM module rear connector) to prevent insertion of a module other than a BOSS type storage module in the BOSS module bay 522. This feature is especially useful to prevent insertion of an OCP type module into the BOSS module bay. In certain embodiments, the OCP module mounting mechanisms include an OCP module rail 550, an OCP module latch 552, an OCP module receiving connector 554, or a combination thereof. In certain embodiments, the OCP module receiving connector 554 includes a 4C OCP module receiving connector.

In certain embodiments, the DC-SCM module receiving connector 534, the BOSS module receiving connector 544, the OCP module receiving connector 554, or a combination thereof, are electrically and physically connected to the HPM portion 512. In certain embodiments, some module mounting mechanisms (e.g., rails and latches) that secure respective modules are physically located on the chassis component portion 514 of the information handling system. In certain embodiments, the module mounting mechanisms (e.g., rails and latches) that secure respective modules are physically located on a base portion of the chassis of the information handling system. In certain embodiments, the base portion of the chassis includes the chassis component. In certain embodiments, the DC-SCM module rail 530, the DC-SCM module latch 532, or a combination thereof, are physically located on the chassis component portion 514. In certain embodiments, the BOSS module rail 540, the BOSS module latch 542, or a combination thereof, are physically located on the chassis component portion 514. In certain embodiments, the OCP module rail 550, the OCP module latch 552, or a combination thereof, are physically located on the chassis component portion 514.

In certain embodiments, the chassis component portion 514 is designed to fit the outline of the HPM portion 512. In certain embodiments, the outline of the HPM portion 512 includes a detachable fan board.

In certain embodiments, the chassis component portion 514 is configured to enable tool-less attachment of the HPM portion 512 with the chassis component portion 514. In certain embodiments, the first configuration (see e.g., FIG. 5B) shows a configuration before the HPM portion 512 is attached to the chassis component 514. In certain embodiments, the second configuration (see e.g., FIG. 5C) shows a configuration with the HPM portion 512 attached to the chassis component portion 514. In certain embodiments, the chassis component portion 514 includes rear retention features 560. In certain embodiments, the HPM portion 512 includes rear retention projections 562. In certain embodiments, the rear retention features 560 secure the HPM portion 512 to the chassis component portion 514. In certain embodiments, the rear retention features 560 secure the HPM portion 512 to the chassis component portion 514 when the rear retention projections 562 are inserted into respective rear retention features 560. In certain embodiments, the rear retention features 560 and the rear retention projections 562 secure the HPM portion 512 to the chassis component portion 514 along a plurality of axis. In certain embodiments, the rear retention features secure the HPM portion 512 to the chassis component portion 514 along three axes.

In certain embodiments, the HPM portion 512 includes manipulation features which facilitate manipulation of the HPM portion 512 when attaching the HPM portion 512 to the chassis component portion 514. In certain embodiments, the manipulation features include a plunger element 570. In certain embodiments, the plunger element 570 vertically extends from the HPM portion 512. In certain embodiments, the plunger element 570 is positioned close to an edge of the HPM portion 512. In certain embodiments, the edge of the HPM portion 512 close to which the plunger portion 570 is positioned includes the edge on which the DC-SCM module receiving connector 534, the BOSS module receiving connector 544, the OCP module receiving connector 554, or a combination thereof, are mounted. In certain embodiments, the manipulation features also include an HPM handle (not shown) mounted close to another edge of the HPM portion 512. In certain embodiments, the another edge includes the edge to which the fan board of the information handling system is connected to the HPM portion 512.

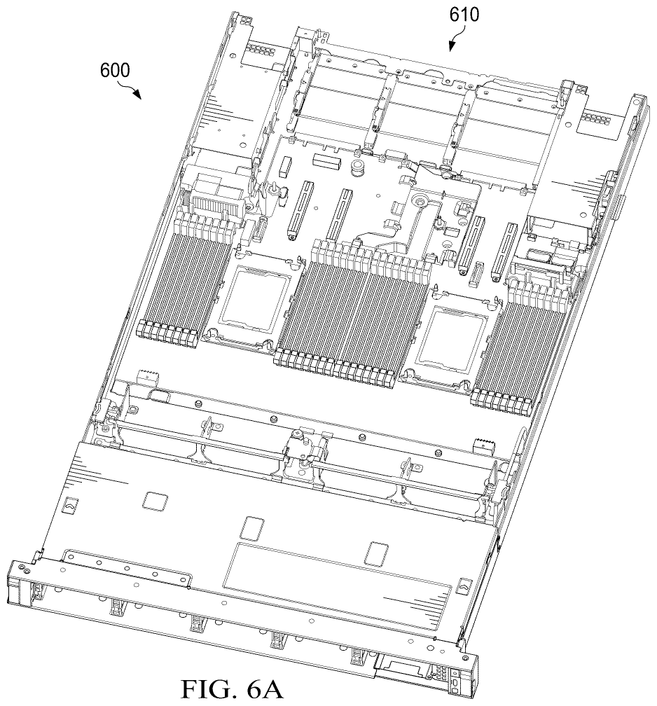

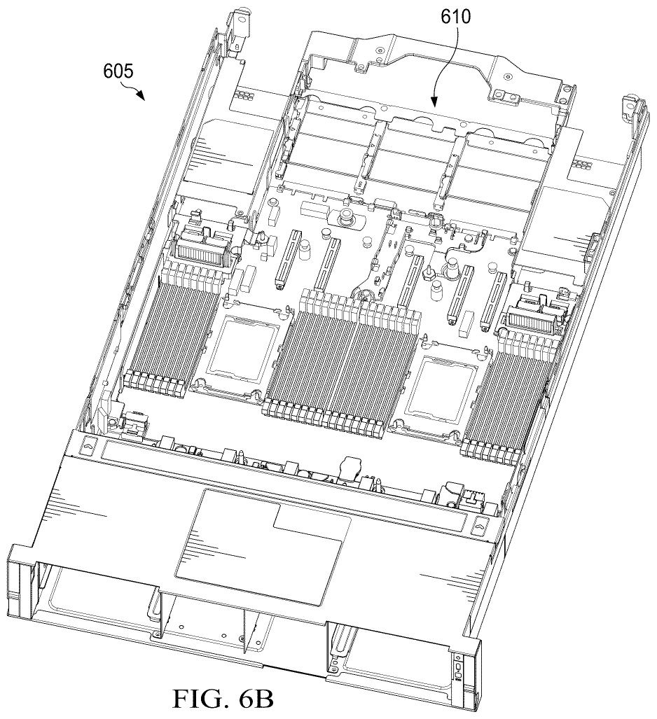

FIGS. 6A and 6B, generally referred to as FIG. 6, show views of information handling systems. More specifically, FIG. 6A shows a cut away top perspective view of an information handling system 600 which includes a bay system 610. FIG. 6B shows a cut away top perspective view of an information handling system 605 which includes a bay system 610. In certain embodiments, the bay system 610 corresponds to bay system 150.

In certain embodiments, the bay system 610 is included within a short chassis component type HPM and a short chassis component. In certain embodiments, the short chassis component type HPM and a short chassis component are mounted within an information handling system 600 conforming to a 1U server size (see e.g., FIG. 6A). In certain embodiments, the short chassis component type HPM and a short chassis component are mounted within an information handling system 605 conforming to a 2U server size (see e.g., FIG. 6B). Accordingly, the bay system 610 provides flexibility to be mounted within chassis having different server size form factors.

The present invention is well adapted to attain the advantages mentioned as well as others inherent therein. While the present invention has been depicted, described, and is defined by reference to particular embodiments of the invention, such references do not imply a limitation on the invention, and no such limitation is to be inferred. The invention is capable of considerable modification, alteration, and equivalents in form and function, as will occur to those ordinarily skilled in the pertinent arts. The depicted and described embodiments are examples only, and are not exhaustive of the scope of the invention.

Consequently, the invention is intended to be limited only by the spirit and scope of the appended claims, giving full cognizance to equivalents in all respects.

What is claimed is:

1. A chassis component for use with a bay system of an information handling system, comprising:
a chassis component portion, the chassis component portion comprising a plurality of module bays, each of a plurality of module receiving connectors being associated with a respective module bay of the plurality of module bays, each of the plurality of module bays including respective module installation features, the respective module installation features ensuring a particular type of module may only be installed in a particular module bay of the plurality of module bays.

2. The chassis component of claim 1, wherein:
each of the plurality of module receiving connectors is configured to receive a particular type of module.

3. The chassis component of claim 2, wherein:
the particular type of module includes at least one of a boot optimized storage system (BOSS) type storage module, an open compute project (OCP) type module, and a data center secure control module (DC-SCM) type module.

4. The chassis component of claim 3, wherein:
the chassis component portion comprises an insertion prevention mechanism, the insertion prevention mechanism preventing installation of modules other than the BOSS type storage module in a module bay configured for receiving the BOSS type storage module.

5. The chassis component of claim 1, wherein:
each respective module installation feature includes a respective bay dimension and respective module mounting mechanisms; the respective installation features being configured to receive a particular type of module.

6. The chassis component of claim 1, wherein:
the chassis component portion is configured to enable tool-less attachment of the host processor module portion.

7. A bay system of an information handling system comprising:
a host processor module portion, the host processor module portion comprising a plurality of module receiving connectors; and,
a chassis component portion, the chassis component portion comprising a plurality of module bays, each of the plurality of module receiving connectors being associated with a respective module bay of the plurality of module bays, each of the plurality of module bays including respective module installation features, the respective module installation features ensuring a particular type of module may only be installed in a particular module bay of the plurality of module bays.

8. The bay system of claim 7, wherein:
each of the plurality of module receiving connectors is configured to receive a particular type of module.

9. The bay system of claim 8, wherein:
the particular type of module includes at least one of a boot optimized storage system (BOSS) type storage module, an open compute project (OCP) type module, and a data center secure control module (DC-SCM) type module.

10. The bay system of claim 9, wherein:
the chassis component portion comprises an insertion prevention mechanism, the insertion prevention mechanism preventing installation of modules other than the BOSS type storage module in a module bay configured for receiving the BOSS type storage module.

11. The bay system of claim 7, wherein:
each respective module installation feature includes a respective bay dimension and respective module mounting mechanisms; the respective installation features being configured to receive a particular type of module.

12. The bay system of claim 7, wherein:
the chassis component portion is configured to enable tool-less attachment of the host processor module portion.

13. A system comprising:
a host processor module, the host processor module including a host processor module portion and a processor, the host processor module portion comprising a plurality of module receiving connectors; and,
a chassis, the chassis including a chassis component portion, the host processor module portion and the chassis component portion providing a bay system, the chassis component portion comprising a plurality of module bays, each of the plurality of module receiving connectors being associated with a respective module bay of the plurality of module bays, each of the plurality of module bays including respective module installation features, the respective module installation features ensuring a particular type of module may only be installed in a particular module bay of the plurality of module bays.

14. The system of claim 13, wherein:
each of the plurality of module receiving connectors is configured to receive a particular type of module.

15. The system of claim 14, wherein:
the particular type of module includes at least one of a boot optimized storage system (BOSS) type storage module, an open compute project (OCP) type module, and a data center secure control module (DC-SCM) type module.

16. The system of claim 15, wherein:
the chassis component portion comprises an insertion prevention mechanism, the insertion prevention mechanism preventing installation of modules other than the BOSS type storage module in a module bay configured for receiving the BOSS type storage module.

17. The system of claim 13, wherein:
each respective module installation feature includes a respective bay dimension and respective module mounting mechanisms; the respective installation features being configured to receive a particular type of module.

18. The system of claim 13, wherein:
the chassis component portion is configured to enable tool-less attachment of the host processor module portion.
